(19) United States
(12) Patent Application Publication
(10) Pub. No.: US 2026/0305214 A1
(43) Pub. Date: Oct. 1, 2026

(54) TRANSPARENT CONDUCTIVE STREETS FOR STEALTH DICING A CONFINEMENT APPARATUS

(71) Applicant: Quantinuum LLC, Broomfield, CO (US)

(72) Inventors: Molly Patricia Andersen, Broomfield, CO (US); Christopher T. Ertsgaard, Champlin, MN (US)

(21) Appl. No.: 19/577,888

(22) Filed: Mar. 25, 2026

Related U.S. Application Data
(60) Provisional application No. 63/778,613, filed on Mar. 27, 2025.

(51) Int. Cl. H10P 58/00

(52) U.S. Cl. CPC H10P 58/00

(57) ABSTRACT

A method is provided. The method includes depositing a transparent conductive layer (TCL) on a wafer. The TCL is characterized by a TCL border. The method further includes singulating the wafer along at least a first portion of a street that is disposed within the TCL border. Singulating the wafer includes stealth dicing the wafer along at least the portion of the street that is disposed within the TCL border. The method further includes depositing a metal layer on a wafer. The metal layer is characterized by a perimeter. The TCL border extends along at least a portion of the perimeter of the metal layer. The metal layer is deposited on the wafer before the TCL is deposited on the wafer. The method further includes patterning the metal layer before the TCL is deposited on the wafer, and patterning the TCL after the TCL is deposited on the wafer.

### CROSS-REFERENCE TO RELATED APPLICATIONS

This application claims the benefit of priority to U.S. Provisional Application No. 63/778,613, titled “TRANSPARENT CONDUCTIVE OXIDE (TCO) STREETS FOR STEALTH DICING A CONFINEMENT APPARATUS” and filed Mar. 27, 2025, the contents of which are herein incorporated by reference in their entirety.

### TECHNICAL FIELD

Various embodiments relate to confinement apparatus assemblies comprising confinement apparatuses configured to confine atomic and/or quantum objects and methods for fabricating confinement apparatus assemblies. Various embodiments relate to fabricating a confinement apparatus using stealth dicing through a transparent conductive layer (TCL) street.

### BACKGROUND

Confinement apparatuses are used to confine or trap atomic and/or quantum objects, such as atoms, ions, molecules, quantum particles, and/or the like. Confinement apparatuses may be formed on portions of wafers that are separated from larger wafers via a number of mechanisms.

Ensuring that the confinement apparatus avoids damage when the portion of the wafer that hosts the confinement apparatus is separated from the larger wafer can be technically difficult. Through applied effort, ingenuity, and innovation many deficiencies of such confinement apparatuses and/or methods of fabrication thereof have been solved by developing solutions that are structured in accordance with the embodiments of the present invention, many examples of which are described in detail herein.

### BRIEF SUMMARY OF EXAMPLE EMBODIMENTS

Example embodiments provide confinement apparatus assemblies, system comprising confinement apparatus assemblies, and methods for fabricating confinement apparatus assemblies. In various embodiments, a confinement apparatus assembly comprises a confinement apparatus comprising a plurality of segmented surface electrodes. Application of voltage signals to the surface electrodes generates an electric potential near the surface of the confinement apparatus that is configured to confine and/or trap one or more atomic and/or quantum objects. In various embodiments, the confinement apparatus assembly further comprises one or more electrical interposer elements, one or more optical and/or photonic interposer elements, magnetic field sources, and/or the like.

According to an embodiment, a method comprises depositing a transparent conductive layer (TCL) on a wafer, the TCL characterized by a TCL border, and singulating the wafer along at least a first portion of a street that is disposed within the TCL border. In some implementations, singulating the wafer comprises stealth dicing the wafer along at least the portion of the street that is disposed within the TCL border. In certain implementations, the method further comprises depositing a metal layer on a wafer, the metal layer characterized by a perimeter. The TCL border extends along at least a portion of the perimeter of the metal layer.

In various implementations, the metal layer is deposited on the wafer before the TCL is deposited on the wafer. In certain embodiments, the method further comprises patterning the metal layer before the TCL is deposited on the wafer, and patterning the TCL after the TCL is deposited on the wafer. In some implementations, the TCL is deposited on the wafer before the metal layer is deposited on the wafer. In further implementations, the method further comprises patterning the TCL before the metal layer is deposited on the wafer, and patterning the metal layer after the metal layer is deposited on the wafer.

In various implementations, the method further comprises patterning the TCL and the metal layer after the metal layer is deposited on the wafer. In certain implementations, the TCL comprises a transparent conductive oxide (TCO). In further implementations, the TCL is transparent in a wavelength range used for stealth dicing the wafer along the street.

According to an embodiment, a device comprises a portion of a wafer and one or more layers formed on the portion of the wafer. A transparent conductive layer (TCL) border is present along at least a portion of a perimeter of a first layer of the one or more layers. In some implementations, the first layer of the one or more layers comprises a metal layer.

In certain implementations the metal layer and the TCL border are disposed on an exposed surface of the device. In further implementations, the device is a confinement apparatus and the metal layer comprises a plurality of electrodes. In various implementations, the device is an ancillary chip, including at least one of a bridge chip, a cloud chip, and an external chip. In some implementations, the TCL border comprises a TCL that is transparent in a wavelength range of a laser used to perform stealth dicing of the wafer to singulate the portion of the wafer therefrom.

In various implementations, the one or more layers includes a photonics routing layer. In certain implementations, the photonics routing layer is configured to cross a street disposed within the TCL border. In further implementations, the portion of the wafer is formed from singulating the wafer along a street, the street disposed within the TCL border and along at least a portion of the perimeter of the first layer of the one or more layers. In certain implementations, singulating the wafer along the street comprises stealth dicing the wafer along the street.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 provides block diagram of an example system comprising a confinement apparatus assembly, in accordance with an example embodiment.

FIG. 2 provides a top view of at least a portion of an example confinement apparatus assembly, in accordance with an example embodiment.

FIG. 3 provides a cross-sectional view of an example confinement apparatus assembly, in accordance with an example embodiment.

FIG. 4 provides a cross-sectional view of another example confinement apparatus assembly, in accordance with various embodiments.

FIG. 5 provides a top view of a wafer including a confinement apparatus having a TCL border, in accordance with various embodiments.

FIGS. 6A and 6B provide flowcharts illustrating various steps of fabricating a confinement apparatus having a TCL border, in accordance with various embodiments.

FIGS. 7A-7D illustrate various steps of fabricating a confinement apparatus having a TCL border, in accordance with various embodiments described herein;

FIG. 8 provides a schematic diagram of an example controller of a system comprising a confinement apparatus assembly, in accordance with an example embodiment.

FIG. 9 provides a schematic diagram of an example computing entity of a system comprising a confinement apparatus assembly that may be used in accordance with an example embodiment.

### DETAILED DESCRIPTION OF SOME EXAMPLE EMBODIMENTS

The present invention now will be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within applicable engineering and/or manufacturing tolerances and/or within user measurement capabilities, unless otherwise indicated. Like numbers refer to like elements throughout.

In various scenarios, atomic and/or quantum objects are confined by a confinement apparatus. In various embodiments, an atomic and/or quantum object is an ion; atom; ionic, molecular, and/or multipolar molecule; quantum dot; quantum particle; group, crystal, and/or combination thereof (e.g., an ion crystal comprising two or more ions); and/or the like. In an example embodiment where the atomic and/or quantum objects are ions and/or ion crystals, the confinement apparatus is an ion trap, such as a surface ion trap, Paul ion trap, and/or the like. In various other embodiments, the confinement apparatus is an apparatus configured to confine atomic and/or quantum objects and comprises a plurality of surface electrodes. For example, in various embodiments, the confinement apparatus is part of a confinement apparatus assembly comprising a substrate that may include one or more optical/photonic and/or electronic interposer layers including one or more vias, routing and/or interconnect layers, photonic/optical layers, and/or the like. In an example embodiment, the confinement apparatus assembly includes a second substrate that is secured in relation to the substrate housing the confinement assembly. For example, the second substrate may house a photonic integrated circuit (PIC) for use as an optical/photonic interposer, one or more magnetic field sources (e.g., permanent magnetic films, integrated circuits that are operable to generate magnetic fields, and/or the like).

In various embodiments, the confinement apparatus comprises a plurality of surface electrodes formed on the substrate of the confinement apparatus assembly. In various embodiments, at least one signal manipulation element (e.g., metasurface, grating, diffractive optical element (DOE), lens, and/or the like) is formed on a surface of an electrode of the plurality of surface electrodes.

In various embodiments, the atomic and/or quantum objects confined by a confinement apparatus are used to perform experiments, controlled quantum state evolution, quantum computations, and/or the like. For example, the confinement apparatus may be part of an atomic system, such as an atomic clock, spectroscopic and/or mass analyzer system, quantum charge-coupled device (QCCD)-based quantum computer, and/or the like.

The optical/photonic interposer layers of the confinement apparatus assembly may be used to provide optical beams and/or signals to respective locations defined at least in part by the confinement apparatus such that the optical beams and/or signals may interact with atomic and/or quantum objects disposed and/or confined at the respective locations. In an example embodiment, the at least one signal manipulation element and/or optical/photonic interposer layer component (e.g., waveguide, grating, coupler, and/or the like) is configured to aid in the collection and/or detection of light emitted and/or fluoresced by atomic and/or quantum objects disposed and/or confined at the respective locations.

Various techniques may be used to singulate a wafer. In general, singulating a wafer includes separating at least a portion of the wafer from a remainder of the wafer using some kind of cutting process. For example, when forming an ion trap, a die (e.g., a portion of a wafer on which electrodes of an ion trap may be formed and/or may be disposed) may be cut from a remainder of the wafer. The die or wafer portion separated from the remainder of the wafer (e.g., the die or wafer portion hosting the ion trap) may be separated from the remainder of the wafer via dicing. In various embodiments, deep reactive ion etching (DRIE) may be used to singulate an ion trap.

However, when the ion trap includes integrated photonics, the ion trap may include optical elements comprising a transparent conductive layer (TCL) on the surface of trap. The TCL may comprise, for example, a transparent conductive oxide (TCO) such as indium tin oxide (ITO). As described in U.S. Provisional Patent Application No. 63/778,776 (titled “CONFINEMENT APPARATUS ASSEMBLY WITH INTEGRATED TRANSPARENT CONDUCTIVE WINDOWS AND METHODS FOR FABRICATION THEREOF”, filed Mar. 27, 2025), the contents of which are hereby incorporated by reference in their entirety, singulation via DRIE requires cleaning processes that TCL features may not survive. Mechanical dicing may be used to singulate an ion trap. However, mechanical dicing may damage fragile micro-electromechanical systems-like structures (e.g., MEMS-like structures) and requires careful cleaning procedures to be performed after singulation. Further, polishing may be required after mechanical dicing. However, the polish residue may require careful cleaning after the polishing is performed.

Another option for singulating ion traps is stealth dicing. To perform stealth dicing, die singulation streets must be transparent at the wavelength of the laser used to perform the stealth dicing. A street, also referred to as a scribe line, is a space outside of a boundary of the ion trap. In some implementations, a street (e.g., a scribe line) may be formed outside a boundary of an ion trap as well as the outside of any other assemblies or integrated circuits fabricated adjacent to the ion trap on the same wafer as the ion trap. In other words, a street may comprise a channel between individual dies of a wafer. However, stealth dicing may lead to exposed facets of dielectric materials deposited on the wafers (e.g., dielectric materials and/or layers deposited on the wafers to form elements on an ion trap, and/or to form elements of other auxiliary chips, such as bridge chips, cloud chips, and/or delivery chips). Such exposed facets may create stray electric fields that interfere with confining potentials meant to trap ions. As such, technical problems arise with respect to manufacturing chips from a wafer

The proposed solution is to define and/or cover the die singulation streets using a transparent conductive layer (TCL). The TCL may comprise, for example, a transparent conductive oxide (TCO). The TCL (e.g., the TCO) may be transparent at the wavelength of a laser generally used for performing stealth dicing. For example, the TCL may be sufficiently transparent (e.g., so as to effectively permit the singulation of a portion of a wafer) at near-infrared (near-IR) wavelengths, such as wavelengths between 700 nm and 3,000 nm. Additionally, the TCL is conductive such that at least a portion of the die may be covered with conductive material, rather than having a border of insulating material at least partially around the portion of the ion trap configured to confine ions. In some implementations, a majority of the surface of the die may be covered with conductive material. The presence of the conductive material on the surface of the die prevents the accumulation of static charge that would otherwise generate electric fields that could interact (e.g., in an undesired or uncontrolled manner) with ions confined by the confinement apparatus.

In accordance with some implementations, the TCL is deposited and patterned at some point during wafer-level fabrication processes of an ion trap and/or a confinement apparatus. For example, the TCL may be deposited and/or patterned before and/or after the deposition and/or patterning of a metal layer of the ion trap/confinement apparatus.

During these processes, TCL may be deposited and patterned to define and/or cover the stealth dicing streets to be used for singulation. Once all wafer-level fabrication processes are completed, the ion trap may be singulated using stealth dicing along at least one edge of the ion trap. During the stealth dicing, the laser may be focused at locations within the wafer that are not photonic layers such that the edges of the photonics layers cleave cleanly/smoothly. After singulation, only minimal and gentle post-processing steps, such as gentle cleans, are required to finish the ion trap.

Various embodiments therefore provide improvements to the technical fields of confinement apparatuses, confinement apparatuses including integrated photonic elements, systems including confinement apparatuses (including confinement apparatuses having integrated photonic elements), methods for fabricating confinement apparatuses (including confinement apparatuses having integrated photonic elements), and quantum computing (e.g., quantum charge-coupled device (QCCD)-based quantum computing).

Example System Comprising an Atomic and/or quantum object Confinement Apparatus

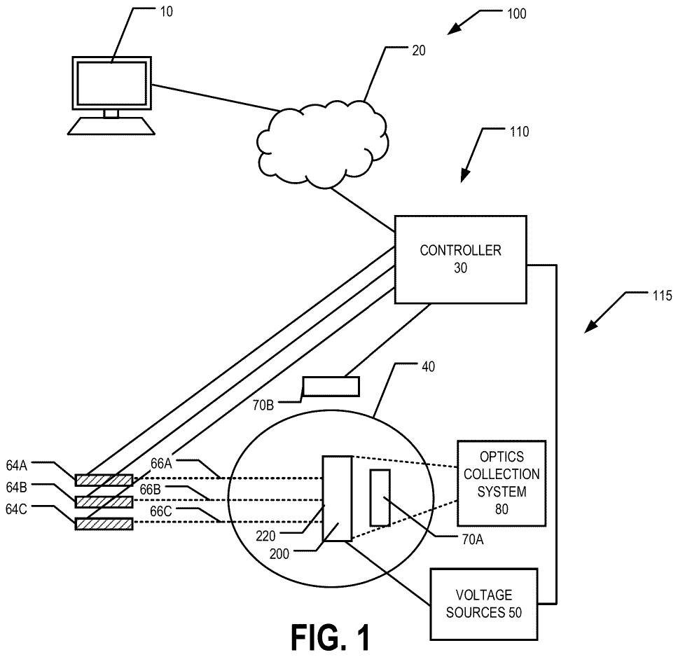

As noted above, various confinement apparatuses of various embodiments may be incorporated into various atomic systems, quantum systems, and/or the like. For example, various embodiments provide a system 100 comprising a confinement apparatus assembly 200, as shown in FIG. 1. The confinement apparatus assembly 200 includes a confinement apparatus 220 configured to confine a plurality of atomic and/or quantum objects such that the respective quantum states of the atomic and/or quantum objects may be manipulated, evolved in a controlled manner (e.g., in accordance with a quantum circuit), and/or the like.

For example, atomic and/or quantum objects may be used as the qubits of a quantum computer 110. For example, quantum operations (one qubit quantum logic gates, two qubit quantum logic gates, initialization, reading/detecting operations, and/or the like) may be performed on atomic and/or quantum objects confined by the confinement apparatus 220 of the confinement apparatus assembly 200. For example, the confinement apparatus 220 is configured to maintain one or more atomic and/or quantum objects at respective locations and/or transport atomic and/or quantum objects between respective locations such that the quantum operation may be performed on the one or more atomic and/or quantum objects.

In various embodiments, the system 100 comprising the confinement apparatus 220 comprises one or more manipulation sources 64 (e.g., 64A, 64B, 64C) configured to provide manipulation signals (e.g., laser beams and/or pulses, microwave signals/fields, and/or the like) such that the manipulation signals interact with one or more atomic and/or quantum objects confined at particular locations defined at least in part by the confinement apparatus 220. In various embodiments, the system 100 comprising the confinement apparatus 220 comprises one or more magnetic field sources 70 (e.g., 70A, 70B) configured to provide a controlled magnetic field and/or magnetic field gradient at particular locations defined at least in part by the confinement apparatus for use in performing one or more quantum operations on one or more atomic and/or quantum objects confined by the confinement apparatus 220. In various embodiments, the system 100 comprising the confinement apparatus 220 comprises an optics collection system 80 configured to collect and/or detect light and/or photons emitted and/or fluoresced by one or more atomic and/or quantum objects disposed at the particular locations defined at least in part by the confinement apparatus 220.

In an example embodiment, the system 100 comprising the confinement apparatus 220 is and/or includes a quantum charge-coupled device (QCCD)-based quantum computer 110. For example, one or more of the atomic and/or quantum objects confined by the confinement apparatus 220 may be used as qubits of the quantum computer 110.

In various embodiments, the system 100 comprises a classical and/or semiconductor-based computing entity 10 and a quantum computer 110. In various embodiments, the quantum computer 110 comprises a controller 30 and a quantum processor 115. In various embodiments, the quantum processor 115 comprises a cryostat and/or vacuum chamber 40 enclosing a confinement apparatus 220, one or more manipulation sources 64 (e.g., 64A, 64B, 64C), one or more voltage sources 50, one or more magnetic field sources 70 (e.g., 70A, 70B), an optics collection system 80, and/or the like. In various embodiments, the controller 30 is configured to control the operation of (e.g., control one or more drivers configured to cause operation of) the manipulation sources 64, voltage sources 50, magnetic field sources 70, a vacuum system and/or cryogenic cooling system (not shown), and/or the like. In various embodiments, the controller 30 is configured to receive signals (e.g., electrical signals) generated and provided by the optics collection system 80.

In an example embodiment, the one or more manipulation sources 64 may comprise one or more lasers (e.g., optical lasers, microwave sources and/or masers, and/or the like) or another manipulation source. In various embodiments, the one or more manipulation sources 64 are configured to manipulate and/or cause a controlled quantum state evolution of one or more atomic and/or quantum objects confined by the confinement apparatus 220. For example, a first manipulation source 64A is configured to generate and/or provide a first manipulation signal and a second manipulation source 64B is configured to generate and/or provide a second manipulation signal, where the first and second manipulation signals are configured to perform one or more quantum operations (single qubit gates, two-qubit gates, cooling, initialization, reading/detection, and/or like) on atomic and/or quantum objects confined by the confinement apparatus.

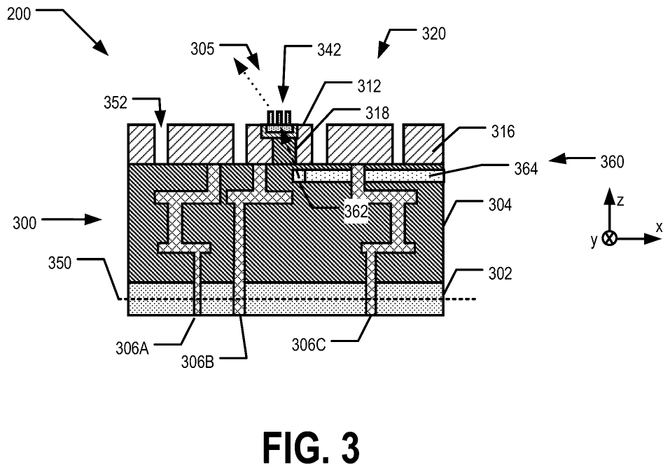

In an example embodiment, the one or more manipulation sources 64 each provide a manipulation signal (e.g., laser beam and/or the like) to one or more regions of the confinement apparatus 220 via corresponding beam path systems 66 (e.g., 66A, 66B, 66C). In various embodiments, at least one beam path system 66 comprises a modulator configured to modulate the manipulation signal being provided to the confinement apparatus 220 via the beam path system 66. In various embodiments, the manipulation sources 64, modulator, and/or other components of the quantum computer 110 are controlled by the controller 30. In various embodiments, at least one beam path system 66A comprises one or more integrated photonic elements formed in (one or more photonics layers of) a substrate of the confinement apparatus assembly 200 (e.g., waveguide 364 and coupler 362 of optical/photonic interposer layer 360 shown in FIG. 3) and/or on a surface of the confinement apparatus (e.g., signal manipulation element 342 of FIG. 3). For example, the signal manipulation element 342 may be part of one or more beam path systems configured to direct manipulation signals (e.g., laser beams and/or pulses) toward a corresponding object location defined at least in part by the confinement apparatus 220.

For example, in various embodiments, a beam path system 66 includes one or more photonic elements (e.g., waveguides, beam splitters, grating couplers, modulators, polarizers, etc.) integrated as part of the confinement apparatus assembly 200 (e.g., housed by the same substrate as the confinement apparatus 220 and/or a photonic integrated circuit (PIC) disposed within the cryostat and/or vacuum chamber 40 and secured with respect to the confinement apparatus 220). In an example embodiment, a beam path system 66 includes one or more optical fibers configured to transport manipulation signals at least partially from a manipulation source 64 to a PIC formed on the same substrate as the confinement apparatus and/or another substrate configured to be secured with respect to the confinement apparatus (e.g., packaged with the substrate housing the confinement apparatus). In an example embodiment, one or more of the manipulation sources 64 are disposed within the cryostat and/or vacuum chamber 40 (e.g., on the same substrate as the confinement apparatus and/or another substrate configured to be secured with respect to the confinement apparatus).

In various embodiments, the confinement apparatus 220 is an ion trap, such as a surface ion trap, Paul ion trap, and/or the like. In various embodiments, the atomic and/or quantum objects are ions; atoms; ion crystals and/or groups; atomic crystals and/or groups; charged, neutral, and/or multipolar molecules; quantum dots; quantum particles; groups, crystals, and/or combinations thereof (e.g., ion crystals); and/or the like. In various embodiments, the confinement apparatus 220 is an appropriate confinement apparatus for confining the atomic and/or quantum objects of the embodiment.

In various embodiments, the quantum computer 110 comprises one or more voltage sources 50. For example, the voltage sources may be arbitrary wave generators (AWG), digital to analog converters (DACs), and/or other voltage signal generators. For example, the voltage sources 50 may comprise a plurality of longitudinal voltage drivers and/or voltage sources and/or at least one RF driver and/or voltage source. The voltage sources 50 may be electrically coupled to the corresponding potential generating elements and/or surface electrodes (e.g., control electrodes and/or RF electrodes) of the confinement apparatus 220, in an example embodiment.

In various embodiments, the quantum computer 110 comprises one or more magnetic field sources 70 (e.g., 70A, 70B). For example, the magnetic field source may be an internal magnetic field source 70A disposed within the cryogenic and/or vacuum chamber 40 and/or an external magnetic field source 70B disposed outside of the cryogenic and/or vacuum chamber 40. In various embodiments, the magnetic field sources 70 comprise permanent magnets, Helmholtz coils, electrical magnets, and/or the like. In various embodiments, the magnetic field sources 70 are configured to generate a magnetic field and/or magnetic field gradient at one or more regions of the confinement apparatus 220 that has a particular magnitude and a particular magnetic field direction in the one or more regions of the confinement apparatus 220.

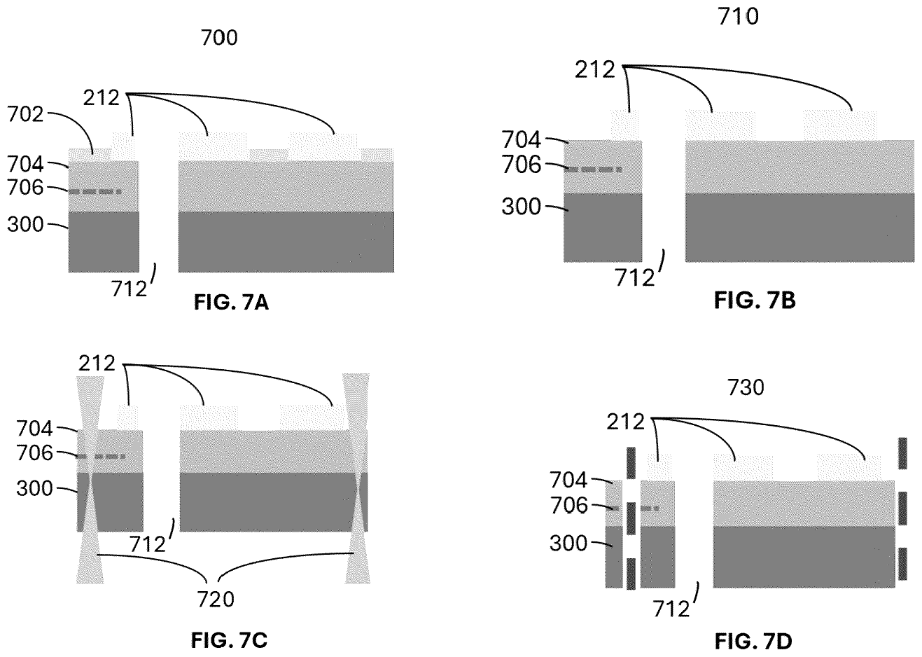

In various embodiments, the quantum computer 110 comprises an optics collection system 80 configured to collect and/or detect photons (e.g., stimulated emission) generated by atomic and/or quantum objects disposed in respective locations (e.g., during reading/detection operations) defined at least in part by the confinement apparatus. The optics collection system 80 may comprise one or more optical elements (e.g., lenses, mirrors, waveguides, fiber optics cables, metasurfaces, and/or the like) and one or more photodetectors. One or more of the optical elements of the optics collection system 80 may be part the optical/photonic interposer layers of the confinement apparatus assembly 200. In an example embodiment, the optics collection system 80 comprises a signal manipulation element formed on a surface of an electrode of the confinement apparatus 220 that is configured to direct light emitted by an atomic and/or quantum object toward a photodetector. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the atomic and/or quantum objects. While the optics collection system 80 is illustrated as being outside of the cryostat and/or vacuum chamber 40, in various embodiments, one or more optical elements and/or the one or more photodetectors of the optics collection system may be disposed within the cryostat and/or vacuum chamber 40. In various embodiments, the detectors may be in electronic communication with the controller 30 via one or more A/D converters 725 (see FIG. 7) and/or the like.

In various embodiments, a computing entity 10 is configured to allow a user to provide input to the quantum computer 110 (e.g., via a user interface of the computing entity 10) and receive, view, and/or the like output from the quantum computer 110. The computing entity 10 may be in communication with the controller 30 of the quantum computer 110 via one or more wired or wireless networks 20 and/or via direct wired and/or wireless communications. In an example embodiment, the computing entity 10 may translate, configure, format, and/or the like information/data, quantum computing algorithms (e.g., quantum circuits), and/or the like into a computing language, executable instructions, command sets, and/or the like that the controller 30 can understand, execute, and/or implement.

In various embodiments, the controller 30 is configured to control the voltage sources 50, magnetic field sources 70, cryogenic system and/or vacuum system controlling the temperature and/or pressure within the cryogenic and/or vacuum chamber 40, manipulation sources 64, and/or other systems controlling various environmental conditions (e.g., temperature, pressure, and/or the like) within the cryogenic and/or vacuum chamber 40, configured to manipulate and/or cause a controlled evolution of quantum states of one or more atomic and/or quantum objects within the confinement apparatus, and/or read and/or detect a quantum (e.g., qubit) state of one or more atomic and/or quantum objects within the confinement apparatus 220. For example, the controller 30 may cause a controlled evolution of quantum states of one or more atomic and/or quantum objects within the confinement apparatus to execute a quantum circuit and/or algorithm. For example, the controller 30 may read and/or detect quantum states of one or more atomic and/or quantum objects within the confinement apparatus 220 at one or more points during the execution of a quantum circuit. In various embodiments, the atomic and/or quantum objects confined by the confinement apparatus are used as qubits of the quantum computer 110.

Example Atomic and/or Quantum Object Confinement Apparatus Assembly

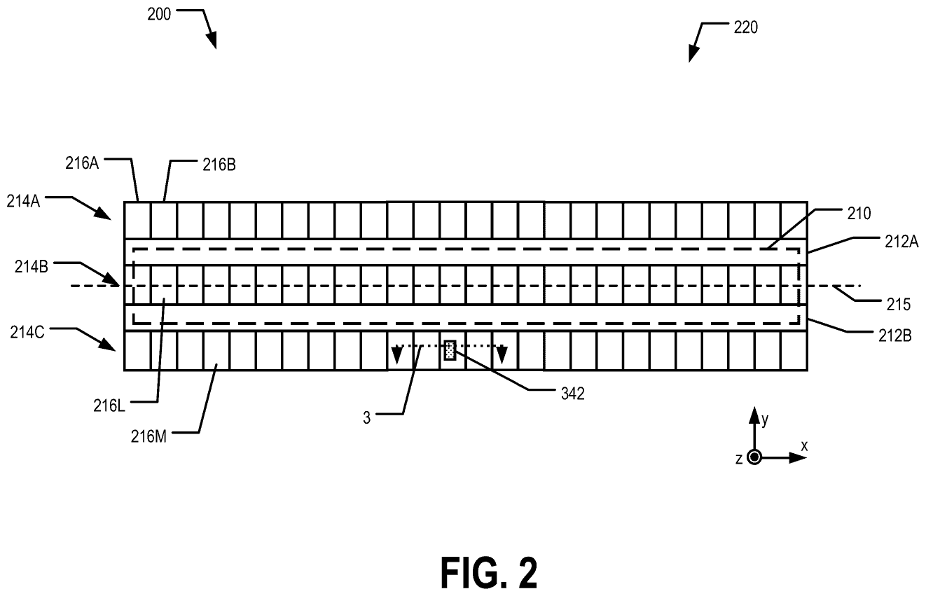

FIGS. 2-5 provide various views of at least portions of some example confinement apparatus assemblies 200. As described in accordance with various embodiments herein, confinement apparatus assemblies may comprise a transparent conducting layer (TCL) and may be formed via stealth dicing. A non-limiting example of a type of material that may be used to form the TCL is a transparent conductive oxide (TCO).

FIG. 2 provides a top view of at least a portion of an example confinement apparatus 220 that may be used to confine one or more atomic and/or quantum objects. For example, in the illustrated embodiment, the confinement apparatus 220 is an ion trap (e.g., a surface ion trap) and the atomic and/or quantum objects are ions and/or ion crystals. The linear portion of the example confinement apparatus 220 may be part of a larger linear geometry of the confinement apparatus or may be part of a two-dimensional or three-dimensional geometry of the confinement apparatus, in various embodiments.

In an example embodiment, the confinement apparatus 220 (e.g., surface ion trap) is fabricated as part of an ion trap chip and/or part of an ion trap apparatus and/or package. For example, the confinement apparatus 220 is formed on a first substrate, such as the substrate 300 of FIG. 3. The first substrate may be a portion of a wafer that is singulated via stealth dicing along a street defined at least in part by a TCO border, in accordance with various embodiments described herein. For example, a TCO border may define a street such that stealth dicing along the street defined by the TCO border preserves a portion of the TCO border on at least one side of the street after singulation. The TCO border, being electrically conductive, prevents the accumulation of static charge on the surface of the confinement apparatus that would otherwise, if the surface of the confinement apparatus were electrically insulating, generate undesired electric fields that could interact with quantum objects confined by the confinement apparatus. In an example embodiment, the confinement apparatus 220 is at least partially defined by a number of RF electrodes 212 (e.g., 212A, 212B). While the RF electrodes 212 are illustrated as generally rectangular, in various embodiments, the RF electrodes 212 may have various geometries, as appropriate for the application.

In various embodiments, the confinement apparatus 220 is at least partially defined by a number of longitudinal sequences of control electrodes 214 (e.g., 214A, 214B, 214C). Each longitudinal sequence of control electrodes 214 comprises a plurality of control electrodes 216 (e.g., 216A, 216B, . . . , 216L, 216M). While the control electrodes 216 are illustrated as generally rectangular, in various embodiments, the control electrodes 216 may have various geometries, as appropriate for the application. In an example embodiment, each control electrode 216 and/or at least a non-empty subset of the control electrodes 216 may be operated independently via the application of control signals thereto. In an example embodiment, at least some of the control electrodes 216 are operated via application of a broadcast control signal.

In an example embodiment, the confinement apparatus 220 is a surface Paul trap with symmetric RF electrodes 212. In various embodiments, the RF electrodes 212 and the control electrodes 216 generate potentials and/or fields that are experienced by atomic and/or quantum objects within respective confinement regions of the confinement apparatus 220. In particular, the RF electrodes 212 may be configured to define the respective confinement regions 210 of the confinement apparatus 220 and the control electrodes 216 may be configured to at least partially control movement and/or motion of atomic and/or quantum objects within the respective confinement regions. For example, the RF electrodes 212 may define an RF null axis 215, along which the atomic and/or quantum objects are confined. For example, the confinement apparatus 220 at least partially defines a plurality of atomic and/or quantum object locations that are generally located along respective RF null axes 215 of respective confinement regions 210.

In various embodiments, a signal manipulation element 342 (e.g., metasurface, DOE, grating, and/or the like) is formed on an electrode surface of one the control electrodes 216 (e.g., 216A, 216L, 216M and/or any other of the control electrodes 216) and/or on a surface of an RF electrode 212. In various embodiments, the signal manipulation element 342 is a metasurface that is formed of an array of metastructures (e.g., nanometer and/or micron scale pillars and/or columns or holes and/or depressions). The optical and/or photonic properties of the metasurface are controlled by the geometry, size, arrangement, and/or orientation of the plurality of metastructures that form the array of metastructures. In various embodiments, the metastructures are nanometer-scale structures. In various embodiments, the metastructures are subwavelength structures. In various embodiments, a subwavelength structure is a structure that extends out from the planarized electrode surface and/or has a diameter/major axis/minor axis/side length that is less than the wavelength of signals that are intended to be incident on the array of metastructures and/or that is less than the wavelength of a signal intended to be emitted by the array of metastructures.

FIG. 3 illustrates a cross-sectional view 320 of a portion an example confinement apparatus assembly 200. For example, FIG. 3 represents a cross-sectional view 320 of the confinement apparatus assembly 200 taken at line 3 in FIG. 2. The confinement apparatus assembly 200 comprises a first substrate 300. The first substrate 300 may be formed on and/or include at least a portion of a wafer 302. The wafer 302 may comprise a portion of a larger wafer that is singulated via stealth dicing along a street defined at least in part by a TCL border, in accordance with various embodiments.

In various embodiments, the first substrate 300 comprises one or more layers disposed thereon. For example, the first substrate 300 comprises one or more electrical interposer layers 304 and, possibly, one or more optical/photonic interposer layers 360. The first substrate 300 may further include a plurality of metal routing features, such as a plurality of vias 306 (e.g., 306A, 306B, 306C), through silicon vias (TSVs), interconnects, and/or the like, as shown in FIG. 3. A plurality of electrodes 316 are formed on the first substrate 300 to form the confinement apparatus 220. Adjacent electrodes of the plurality of electrodes 316 are separated from one another by gaps 352.

The plurality of electrodes 316 may be formed from a metal layer (also referred to herein as a top metal layer and/or a topmost metal layer) of the confinement apparatus assembly 200. The plurality of electrodes of the metal layer may be characterized by a perimeter. A TCL border may be present along at least a portion of a perimeter of a first layer of the one or more layer. For example, a TCL border may be disposed along at least a portion of the perimeter of the metal layer that comprises the plurality of electrodes 316. The TCL border may define a street along which the portion of the wafer 302 is singulated (e.g., the TCL border may define a street along which the substrate 300 formed on and/or including the wafer 302 is damaged by exposure to laser radiation such that the portion of the wafer 302 may be singulated). The portion of the wafer 302 may be singulated via stealth dicing.

The confinement apparatus assembly 200 may comprise a signal manipulation element 342. The signal manipulation element 342 is configured such that a beam of light may be incident thereon, as shown by the dashed line. The light interacts with the signal manipulation element 342 such that an induced beam is provided, as shown by the dotted line. The induced beam may have various optical properties that are controlled by a signal manipulation element 342, such as polarization, wavelength, relative phase delay, direction of propagation, beam profile, focal point, and/or the like.

In an example embodiment, such as that illustrated in FIG. 3, the confinement apparatus assembly 200 includes one or more optical/photonic interposer layers 360 that each include respective integrated photonic elements such as a waveguide 364 and a coupler 362. For example, in various embodiments, one or more electrodes 316 include respective windows 318. For example, window 318 comprises a dielectric material that is transparent to light of at least a selected frequency range. A window 318 may extend across one or more electrodes 316.

For example, a dielectric window 318 may extend through the bulk material of an electrode 316 to allow light to pass therethrough. The conductive material of the electrode 316 may be deposited around the window 318 such that the window 318 is embedded within the electrode 316. In various embodiments, the coupler 362 is aligned with the window 318 such that the coupler 362 couples light out of the waveguide 364 and out through the window 318, as shown by the dashed arrow. The window 318 may comprise a post and/or a pillar of dielectric material that is transparent to light of at least a selected frequency range. The post and/or the pillar of the dielectric material may be characterized by a height. The window 318 may comprise a flat portion of dielectric material having substantially zero height.

In some implementations, the light coupled out of the waveguide 364 by the coupler 362 is incident on the signal manipulation element 342, and the interaction of the light and the signal manipulation element 342 causes an induced beam, as shown by the dotted line, to be emitted. The induced beam may have various optical properties that are controlled by signal manipulation element 342, such as polarization, wavelength, relative phase delay, direction of propagation, beam profile, focal point, and/or the like. In certain implementations, the light coupled out of the waveguide 364 by the coupler 362 propagates out of the window 318 to a downstream location without modification of an optical property of the light by a signal manipulation element 342.

As shown in FIG. 3, in some embodiments, a window 318 is capped by a cap 305 formed of a conductive material (e.g., a TCL) that is transparent to light of at least a selected frequency range. The cap 305 may be referred to herein as a “TCL cap”. The TCL cap 305 may be transparent in a wavelength range of a laser used to perform stealth dicing, in accordance with various embodiments described herein.

In some implementations, the cap 305 may be recessed into an electrode 316 to form a flush electrode surface. In certain implementations, the cap 305 comprises a recessed cap (e.g., the cap 305 is recessed with respect to the electrode 316). In certain implementations, the cap 305 is coplanar with a top surface 312 of the electrode 316. In further implementations, the cap 305 may be disposed on the top surface 312 of the electrode 316. In various implementations, the TCL cap 305 is disposed beneath the electrode 316.

In an example embodiment, the coupler 362 is configured to couple light that passed through the signal manipulation element 342 and the window 318 into the waveguide 364. For example, the signal manipulation element 342 may be configured to direct light incident thereon toward the coupler 362 such that the coupler 362 may couple the light into the waveguide 364 (e.g., for detection by a photodetector of the optics collection system 80 of FIG. 1).

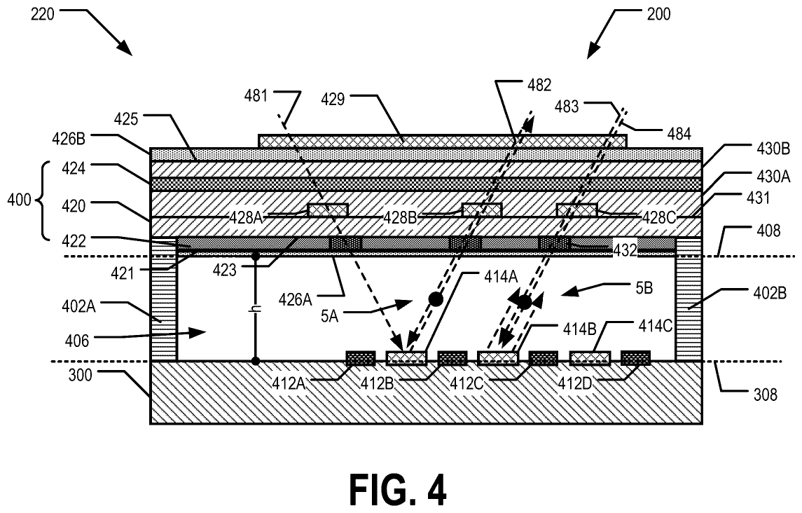

FIG. 4 provides a schematic cross-section view of an example embodiment of a confinement apparatus assembly 200 that includes a first substrate 300. The first substrate 300 of FIG. 4 may comprise the first substrate 300 of FIG. 3.

The first substrate 300 of FIG. 4 may or may not include one or more optical/photonic interposer layers (e.g., the optical/photonic interposer layers 360 of FIG. 3), one or more electrical interposer layers (e.g., the one or more electrical interposer layers 304 of FIG. 3), and/or vias (e.g., vias 306 of FIG. 3). The first substrate 300 of FIG. 4 may further have a plurality of electrical components 412 (e.g., 412A, 412B, 412C) of a confinement apparatus (e.g., the confinement apparatus 220 of FIG. 2) formed thereon.

The confinement apparatus assembly 200 illustrated in FIG. 4 also includes a second substrate 400 that is secured with respect to the first substrate 300. In an example embodiment, the second substrate 400 houses a photonic integrated circuit (PIC) and/or one or more optical/photonic interposer layers. The second substrate 400 may also house one or more magnetic field or magnetic field gradient sources, electrodes, electrical interposer layers, and/or the like.

In an example embodiment, the second substrate 400 and the first substrate 300 are coupled to one another and/or secured into relationship with one another via spacing structures 402 (e.g., 402A, 402B). In an example embodiment, the spacing structures 402 are formed of solid material. In an example embodiment, the spacing structures 402 are nano-positioners. For example, the spacing structures 402 may comprise piezoelectric actuators configured to enable fine-tuned alignment of the second substrate 400 with the first substrate 300. The second substrate 400 may include one or more optical/photonic interposer layers (e.g., including waveguide 424, signal manipulation elements 428A, 428B, 428C), one or more magnetic field and/or magnetic field gradient sources, and/or the like.

In various embodiments, the first substrate 300 and/or confinement apparatus 220 defines an apparatus plane 308. In various embodiments, the second substrate 400 defines a cloud plane 408. In various embodiments, the cloud plane 408 is parallel to the apparatus plane 308, but not coplanar with the apparatus plane 308. For example, the cloud plane 408 and the apparatus plane 308 are separated by a set distance h. The relationship between the cloud plane 408 and the apparatus plane 308 is controlled and/or maintained by the spacing structures 402. For example, the set distance h and/or the parallel relationship between the cloud plane 408 and the apparatus plane 308 is controlled and/or maintained by the spacing structures 402.

In various embodiments, the confinement apparatus assembly 200 comprises one or more bridge chips that each define a respective bridge plane. The respective bridge planes may be coplanar with the apparatus plane. Each of the one or more bridge chips may have one or more optical elements disposed and/or formed thereon and/or therein. In various embodiments, a bridge chip is configured to provide manipulation signals and/or other optical signals to one or more optical elements disposed on an ion trap chip of the confinement apparatus, the bridge chip, and/or other chips (e.g., a cloud chip, an external chip, and/or the like). In various embodiments, a bridge chip may span regions that involve varying temperatures and/or pressures (e.g., within a cryogenic and/or vacuum chamber within which the confinement apparatus 220 is disposed. In various embodiments, a bridge chip may comprise a surface that is substantially coplanar with a surface of the confinement apparatus 220.

In various embodiments, the confinement apparatus assembly 200 comprises one or more delivery chips. The delivery chip may have one or more optical elements disposed and/or formed thereon and/or therein. In various embodiments, a delivery chip is configured to provide manipulation signals and/or other optical signals to one or more optical elements disposed on an ion trap chip of the confinement apparatus assembly 200, one or more bridge chips, the delivery chip, and/or defined positions of the confinement apparatus assembly 200.

In various embodiments, a delivery chip may be disposed within the cryogenic and/or vacuum chamber in which the confinement apparatus assembly 200 is disposed or external thereto. In various embodiments, delivery chips may be configured in various physical orientations. For example, a delivery chip may define a delivery chip plane that may be disposed in various orientations with respect to the apparatus plane 308. For example, a delivery chip may be mounted to a wall and/or a shielding surface of the cryogenic and/or vacuum chamber within which the ion trap chip is disposed. For example, the delivery chip comprises a surface that is not coplanar with the surface of the confinement apparatus 220 (also referred to herein as the apparatus plane). For example, the delivery chip may comprise a surface that is substantially perpendicular to the surface of the confinement apparatus 220 or substantially parallel to (but not coplanar with) the surface of the confinement apparatus 220.

An example of a delivery chip is a cloud chip. In various embodiments, the confinement apparatus assembly 200 comprises one or more cloud chips that each define a respective cloud plane that is parallel to the apparatus plane 308 but not coplanar with the apparatus plane. For example, a cloud chip defines a cloud plane that is parallel to the apparatus plane 308 and that is spatially separated from the apparatus plane 308 in a direction perpendicular to the apparatus plane 308. Each of the one or more cloud chips may have one or more optical elements disposed and/or formed thereon and/or therein.

In various embodiments, the confinement apparatus system comprises one or more external chips (e.g., one or more photonic integrated circuits (PICs)). In some embodiments, a least a portion (e.g., some or all) of each of the optical elements (e.g., opto-electronic sensors, light sources (e.g., lasers, LEDs, or the like), photonic components (e.g., passive photonic components, active photonic components) and/or electronic elements of the confinement apparatus system are disposed and/or formed on the confinement apparatus chip. Alternatively or additionally, in some embodiments, at least a portion (e.g., some or all) of each of the optical elements (e.g., opto-electronic sensors, light sources (e.g., lasers, LEDs, or the like), photonic components, and/or the like) and/or electronic elements of the confinement apparatus system are disposed and/or formed on a bridge chip of the confinement apparatus system. Alternatively or additionally, in some embodiments, at least a portion (e.g., some or all) of each of the optical elements (e.g., opto-electronic sensors, light sources (e.g., lasers, LEDs, or the like), photonic components, and/or the like) and/or electronic elements of the confinement apparatus system are disposed on a cloud chip of the confinement apparatus system. Alternatively or additionally, in some embodiments, at least a portion (e.g., some or all) of the optical elements (e.g., optoelectronics sensors, light sources (e.g., lasers, LEDs, or the like), photonic components, and/or the like) and/or electronic elements of the confinement apparatus system are disposed on an external chip of the confinement apparatus system. In this regard, in some embodiments, the confinement apparatus system may comprise one or more ancillary chips (e.g., bridge chips, cloud chips, external chips, and/or other chips). As used herein, an ancillary chip refers to any distinct chip (relative to the confinement apparatus chip) that includes co-integrated photonics-electronics (as described herein) configured to interface with a confinement apparatus chip.

In various embodiments, a bridge chip and/or delivery chip may be disposed in a region of substantially constant temperature and/or pressure conditions. For example, the bridge chip and/or delivery chip may be disposed within an action region of the cryogenic and/or vacuum chamber such that the bridge chip and/or delivery chip is operated under cryogenic and/or ultra-high vacuum conditions. In various embodiments, the confinement apparatus chip is disposed within the action region of the cryogenic and/or vacuum chamber and configured to be operated under cryogenic and/or ultra-high vacuum conditions. The bridge chip and/or delivery chip may be disposed in an intermediary area of the cryogenic and/or vacuum chamber (e.g., within the cryogenic and/or vacuum chamber but in an intermediate region thereof that experiences intermediate temperatures and/or pressures that are between ambient temperature and/or pressure outside of the cryogenic and/or vacuum chamber and the very low cryogenic temperatures and ultra-high vacuum conditions within the action region of the cryogenic and/or vacuum chamber). In an example embodiment, a delivery chip may be disposed outside of the cryogenic and/or vacuum chamber.

In various embodiments, a bridge chip and/or delivery chip may be partially disposed in and/or extend across one or more regions of the cryogenic and/or vacuum chamber. As used herein, the regions of the cryogenic and/or vacuum chamber include the action region of the cryogenic and/or vacuum chamber (e.g., having very low temperatures and ultra-high vacuum conditions), the intermediate region of the cryogenic and/or vacuum chamber (e.g., having intermediate temperatures and intermediate pressures), and an ambient region (directly) outside of the cryogenic and/or vacuum chamber (e.g., having ambient/room temperatures and/or ambient/atmospheric pressure). For example, a portion of a bridge chip and/or delivery chip may be disposed in the action region of the cryogenic and/or vacuum chamber and a portion of the bridge chip may be disposed in the intermediate region of the cryogenic and/or vacuum chamber.

In various embodiments, the confinement apparatus chip defines a plurality and/or an array of defined positions. For example, the confinement apparatus chip may be configured such that when appropriate voltage signals are applied to electrical components (e.g., electrodes) thereof, an electric potential is generated that is configured to confine quantum objects at the defined positions. In various embodiments, a sub-array of defined positions may be configured for performing a particular function (e.g., a reading function, performance of a single qubit or multi-qubit (e.g., two qubit) gate, and/or the like. In various embodiments, the optical elements disposed on the confinement apparatus chip, bridge chip(s), delivery chip(s), and/or external chip(s) that are configured for performance of the particular function are arrayed on their respective chips/substrates accordingly.

A confinement apparatus volume 406 is defined and/or disposed between the first substrate 300 and the second substrate 400. The confinement regions generated through the operation of the electrical components 412 (e.g., 412A, 412B, 412C, 412D) of the confinement apparatus 220 (which are formed on the first substrate 300) are disposed within the confinement apparatus volume 406 defined between the confinement apparatus 220 and the second substrate 400. For example, the electrical components 412 may be RF electrodes (e.g., the RF electrodes 212 of FIG. 2) and/or control electrodes (e.g., the control electrodes 216 of FIG. 2) of the confinement apparatus (such that the confinement apparatus 220 of FIG. 2). For example, the object locations 5 (e.g., 5A, 5B) defined at least in part by the confinement apparatus are within the confinement apparatus volume 406 defined between the confinement apparatus (formed on the first substrate 300) and the second substrate 400.

For example, the controller 30 of FIG. 1 may control the voltage sources 50 of FIG. 1 to provide electrical signals to the electrical components 412 of the confinement apparatus 220 such that the electrical components 412 generate a confining potential. The confining potential is configured to confine a plurality of atomic and/or quantum objects within one or more confinement regions defined by the confinement apparatus 220 and disposed within the confinement apparatus volume 406 between the first substrate 300 and the second substrate 400. In various embodiments, the electrical components 412 and/or confining potential are configured to define a plurality of object locations 5 within the confinement region(s) and/or confinement apparatus volume 406. The object locations 5 may be disposed in a one-dimensional, two-dimensional, or three-dimensional layout.

In various embodiments, one or more optical components 414 (e.g., 414A, 414B, 414C) are formed on the first substrate 300. For example, the one or more optical components 414 may be signal manipulation elements, such as the signal manipulation elements 342 of FIG. 3. In various embodiments, the one or more optical components 414 comprise flat optics (e.g., metasurfaces, DOEs), guided mode photonics (e.g., waveguides), microfabricated lenses, and/or the like. For example, in various embodiments, the photonic components and/or optical components 414 formed on and/or in the first substrate 300 include one or more DOEs, passive metasurfaces, active metasurfaces, optical modulators, low loss waveguides, amplifiers, on-chip lasers, photodetectors, grating couplers, beam splitters, edge couplers, optical local oscillators, tapers, reference cavities, optical sinks, light absorbing structures, anti-reflection coatings, optical routing elements, resonant structures, and/or the like. In various embodiments, the one or more optical components 414 are configured to control parameters (e.g., wavelength, focus, polarization, phase, direction of propagation, and/or intensity) and/or provide manipulation signals to respective object locations. For example, an optical component 414 is associated with a respective object location 5 such that the optical component 414 is part of an optical path for providing a respective manipulation signal to the respective object location to cause a respective function to be performed one or more quantum objects disposed at the respective object location.

The confinement apparatus assembly 200 of FIG. 4 further includes a second substrate 400 housing photonic components. For example, the second substrate 400 may house a PIC. In the illustrated embodiment, the photonic components of the second substrate 400 include cladded photonic components (e.g., 428A, 428B, 428C) and exposed photonic components 429. In various embodiments, the cladded photonic components include one or more waveguide layers 424. In various embodiments, the one or more photonic components (e.g., cladded photonic components 428 and/or exposed photonic components 429) comprise flat optics (e.g., metasurfaces, DOEs), guided mode photonics (e.g., waveguides), microfabricated lenses, and/or the like. For example, in various embodiments, the photonic components of the signal management system comprise one or more DOEs, passive metasurfaces, active metasurfaces, optical modulators, low loss waveguides, amplifiers, on-chip lasers, photodetectors, grating couplers, beam splitters, edge couplers, optical local oscillators, tapers, reference cavities, optical sinks, light absorbing structures, anti-reflection coatings, optical routing elements, resonant structures, and/or the like. In various embodiments, the one or more photonic components are configured to control parameters (e.g., wavelength, focus, polarization, phase, direction of propagation, and/or intensity) and/or provide manipulation signals to respective object locations. For example, a photonic component is associated with a respective object location 5 such that the photonic component is part of an optical path for providing a respective manipulation signal to the respective object location to cause a respective function to be performed one or more quantum objects disposed at the respective object location.

In various embodiments, the second substrate 400 is transparent to light and/or electromagnetic signals characterized by a wavelength within a particular wavelength range. In various embodiments, the manipulation signals provided to the respective object locations are characterized by wavelengths within the particular wavelength range. For example, the second substrate 400 is transparent to the manipulation signals, in various embodiments. In various embodiments, one or more waveguides, waveguide layers 424, and/or cladded photonic components 428 are formed on the second substrate 400. Cladding layers 430 (e.g., 430A, 430B) may then be deposited and/or formed on the one or more waveguides, waveguide layers 426, and/or cladded photonic components 428 so as to clad the one or more waveguides, waveguide layers 426, and/or cladded photonic components 428. In various embodiments, several alternating layers of waveguides, waveguide layers 426, and/or cladded photonic components 428 and corresponding cladding layers 430 may be sequentially formed on the second substrate 400. In various embodiments, the cladding layers 430 and the second substrate 400 are formed of the same material and/or material that has similar optical properties (e.g., similar refractive indices, absorption coefficients, and/or transmission coefficients for manipulation signals characterized by wavelengths within the particular wavelength range).

For example, in the illustrated example embodiment, a plurality of cladded photonic components 428 are formed on a first surface 431 of a substrate layer 420 of the second substrate 400. For example, the substrate layer 420 provides a structural component upon which the remainder of the second substrate 400 may be formed. The first surface 431 of the substrate layer 420 is configured to face away from the first substrate 300, in the illustrated embodiment. A first cladding layer 430A is then deposited and/or formed on the first surface 431 of the substrate layer 420 and the cladded photonic components 428 formed thereon. A waveguide layer 424 is formed on the first cladding layer 430A and a second cladding layer 430B is formed on the waveguide layer 424. Various layers of waveguides and/or other photonic components (e.g., flat optics, guided mode photonics, microfabricated lenses) and corresponding cladding layers may be formed on the first surface 431 of the substrate layer 420, as appropriate for the application, to form the second substrate 400.

In various embodiments, the substrate layer 420 and/or cladding layer(s) 430 comprises glass, sapphire, or fused quartz. Various other materials may be used for forming the substrate layer 420 and/or cladding layer(s) 430, in various embodiments, as appropriate for the application. For example, the substrate layer 420 and/or cladding layer(s) 430 comprises silicon dioxide, silicon nitride, aluminum oxide, or silicon carbide, etc.

In various embodiments, the cladded photonic components 428, waveguides, and/or waveguide layers 424 are configured to cause respective manipulation signals to be incident on respective object locations 5 defined by the confinement apparatus 220. In various embodiments, the cladded photonic components 428, waveguides, and/or waveguide layers 424 are configured to control parameters (e.g., wavelength, focus, polarization, phase, direction of propagation, and/or intensity) of respective manipulation signals provided to respective object locations 5.

In various embodiments, the cladded photonic components 428, waveguides, waveguide layers 424, and cladding layers are formed on the second surface 423 of the substrate layer 420 to form the second substrate 400 (e.g., rather than and/or in addition to the first surface 431). In various embodiments, respective cladded photonic components 428, waveguides, waveguide layers 424, and cladding layers are formed on both the first surface 431 and the second surface 423 of the substrate layer 420 to form the second substrate 400.

In various embodiments, an anti-reflection coating 426B is applied to the first surface 425 of the second substrate 400. For example, the anti-reflection coating 426B may be applied, formed, and/or deposited on the first surface 425 of the second substrate 400. In various embodiments, the anti-reflection coating 426B is engineered to minimize and/or reduce the reflection of light off of the first surface 425. For example, the anti-reflection coating 426B is configured, engineered, and/or designed, to increase and/or maximize the transmission coefficient across the first surface 425. In various embodiments, the first surface 425 of the second substrate 400 is configured to face away from the first substrate 300.

In various embodiments, exposed photonic components 429 are disposed on the first surface 425 of the second substrate 400. For example, the exposed photonic components 429 are formed on the anti-reflection coating 426B, in an example embodiment. In various embodiments, the exposed photonic components 429 include one or more of flat optics (e.g., metasurfaces, DOEs), guided mode photonics (e.g., waveguides), microfabricated lenses, and/or the like. For example, in various embodiments, the exposed photonic components comprise DOEs, passive metasurfaces, active metasurfaces, optical modulators, low loss waveguides, amplifiers, on-chip lasers, photodetectors, grating couplers, beam splitters, edge couplers, optical local oscillators, tapers, reference cavities, optical sinks, light absorbing structures, optical routing elements, resonant structures, and/or the like. For example, in various embodiments, the exposed photonic components 429 include one or more metasurfaces, a metasurface array, one or more lenses, a lenslet array, and/or the like. In an example embodiment, the exposed photonic component 429 is configured to couple manipulation signals into the second substrate 400.

A second surface 423 of the second substrate 400 is configured to face the first substrate 300. In various embodiments, a conductive layer 422 is disposed, deposited, and/or formed on the second surface 423 of the substrate layer 420 and/or second substrate 400. In various embodiments, the conductive layer 422 comprises an electrically conductive material. In various embodiments, the conductive layer 422 is configured to be held at a fixed electric potential. For example, the conductive layer 422 may be in electrical communication with a ground and/or a voltage source configured to cause the conductive layer 422 to be held at a fixed electric potential. In an example embodiment, a portion of the conductive layer 422 may be used to generate a magnetic field and/or magnetic field gradient.

In various embodiments, at least one or more sections of the conductive layer 422 are transparent for electromagnetic radiation characterized by wavelengths within the particular wavelength range. In other words, the conductive layer 422 may comprise a transparent conductive layer (TCL). In various embodiments, the conductive layer 422 comprises a transparent conductive oxide (TCO).

In various embodiments, the conductive layer 422 is a transparent conductive film and/or layer. For example, the conductive layer 422 may be formed of indium tin oxide (ITO) or another transparent conductive material. In various embodiments, the conductive layer 422 comprises one or transparent sections 432. For example, the conductive layer 422 may be formed of a non-transparent conductive material. The one or more transparent sections 432 may be windows opened in the non-transparent conductive material (e.g., via etching, masked or lithographic deposition of the non-transparent conductive material, and/or the like). In various embodiments, the one or more transparent sections 432 are formed of a transparent conductive material, are empty openings in the conductive material of the conductive layer 422, and/or the like.

In various embodiments, a confinement apparatus-facing surface 421 of the conductive layer 422 (and/or portions thereof) has anti-reflective characteristics. In various embodiments, an anti-reflection coating 426A is applied, deposited, and/or disposed on the confinement apparatus-facing surface 421 of the conductive layer 422. In certain embodiments, an anti-reflection coating may be applied between the conductive layer 422 and the substrate layer 420 of the confinement apparatus assembly 200. In various embodiments, the anti-reflection coating 426A is engineered to minimize and/or reduce the reflection of light off of the confinement apparatus-facing surface 421. For example, the anti-reflection coating 426A is configured, engineered, and/or designed, to increase and/or maximize the transmission coefficient across the confinement apparatus-facing surface 421. In various embodiments, the confinement apparatus-facing surface 421 is configured to face the first substrate 300.

In various embodiments, the conductive layer 422 comprises a plurality of patterned electrodes. For example, in an example embodiment, the conductive layer 422 comprises a plurality of patterned electrodes configured to form a confinement apparatus. For example, the conductive layer 422 may comprise a plurality of patterned electrodes configured to form a secondary confinement apparatus that is independent (or largely independent) of the confinement apparatus 220 formed on the first substrate 300. For example, the conductive layer 422 may comprise a plurality of patterned electrodes configured to form, in coordination with the electrical components 412 formed on the confinement apparatus 220 to form a three-dimensional (3D) confinement apparatus.

The manipulation signals 481, 482, 483, 484 illustrate some example interactions between manipulation signals and optical/photonic components of the first substrate 300 (e.g., optical components 414 and optical components of the second substrate 400). For example, a first manipulation signal 481 is provided to the second substrate 400 such that the first manipulation signal 481 is conditioned (e.g., has one or more parameters thereof controlled) by the exposed photonic component 429 and the first cladded photonic component 428A. The first manipulation signal 481 is then reflected and/or further conditioned by a first optical component 414A. A second manipulation signal 482 is provided to the second substrate 400 such that the second manipulation signal 482 is conditioned (e.g., has one or more parameters thereof controlled) by the exposed photonic component 429 and the second cladded photonic component 428B. The first manipulation signal 481 and the second manipulation signal 482 pass through the first object location 5A such that the first manipulation signal 481 and the second manipulation signal are co-axial, but propagating in opposite directions. In various embodiments, such a configuration may be used to perform a two-qubit gate and/or other quantum logical operation at the first object location 5A. For example, the co-axial counter-propagating (reflected) first manipulation signal 481 and the second manipulation signal 482 may be used to perform a two-qubit gate and/or other quantum logical operation at the first object location 5A.

In another example, at a second object location 5B, a third manipulation signal 483 and a fourth manipulation signal 484 are provided along a common optical path to provide coaxial counter-propagating manipulation signals at the second object location 5B. The third manipulation signal 483 and the fourth manipulation signal 484 are provided during an overlapping time period such that the third manipulation signal 483 and the fourth manipulation signal 484 are both incident on the second object location 5B during a particular time window. For example, the third manipulation signal 483 and the fourth manipulation signal 484 are both provided to the second substrate 400 such that the third manipulation signal 483 and the fourth manipulation signal 484 are conditioned (e.g., have one or more parameters thereof controlled) by the exposed photonic component 429 and the third cladded photonic component 428C. The third manipulation signal 483 and the fourth manipulation signal 484 are reflected and/or further conditioned by a second optical component 414B. The reflect third manipulation signal 483 and the reflected fourth manipulation signal 284 pass back through the second object location 5B to provide the co-axial counter-propagating manipulation signals (e.g., the third manipulation signal 483 interacting with the reflected fourth manipulation signal and the fourth manipulation signal 484 interacting with the reflected third manipulation signal). For example, in an example embodiment, the second optical component 414B is a retroreflector. In various embodiments, such a configuration may be used to perform a two-qubit gate and/or other quantum logical operation at the second object location 5B. For example, the co-axial counter-propagating third manipulation signal and reflected fourth manipulation signal and the co-axial and counter-propagating reflected third manipulation signal and the fourth manipulation signal may be used to perform a two-qubit gate and/or other quantum logical operation at the second object location 5B. In an example embodiment, wherein the second optical component 414B is a retroreflector, the co-axial counter-propagating third manipulation signal and reflected fourth manipulation signal and the co-axial and counter-propagating reflected third manipulation signal and the fourth manipulation signal generate a phase-stable interference pattern.

FIG. 5 illustrates a wafer or portion of a wafer 500. The wafer 500 of the embodiment of FIG. 5 comprises a confinement apparatus 520 (such as, for example, the confinement apparatus 220 of FIG. 2) or other device with a metal layer (e.g., electrodes) formed on a top thereof. In certain implementations, the wafer 500 comprises one or more layers disposed and/or formed on a top thereof.

Ions confined within ion traps may be screened from stray fields generated by dielectric components of the ion traps. For example, ion traps may comprise integrated photonics that require controlled edge facets that are compatible with coupling lighting into waveguides. TCLs, including TCOs or other transparent conductors, may be used to electrically screen ions confined within ion traps, including ion traps comprising such integrated photonics, from such stray fields. Maintaining the integrity of the TCL through singulation of the ion trap die, while also avoiding the exposed dielectric, can require extensive die-level processing.

As described herein, disposing a TCO in the die singulation streets around the edges of the die enables die singulation via stealth dicing while avoiding any exposed dielectric materials (e.g., an exposed oxide) on a trap die surface. As shown in FIG. 5, a transparent conducting oxide (TCO) border 510 is formed around at least a portion of the perimeter 522 of the confinement apparatus 520. The perimeter 522 may be defined, at least in part, by a topmost layer disposed on the wafer 500, (e.g., a topmost metal layer comprising at least one electrode of the confinement apparatus 520).

When singulation is performed to form the confinement apparatus 520, dicing may be performed along the street 530. For example, stealth dicing may be performed along the street 530. Once the singulation is performed, along at least the portion of the perimeter 522 where the stealth dicing was performed, a TCO border 510 is present. The TCO border 510 may be present on at least one side of the street 530 along which stealth dicing was preserved. The TCO border 510 prevents the accumulation of static charge on the surface of the confinement apparatus 520. Thus, the TCO border 510 prevents the formation of stray electric fields on the surface of the confinement apparatus 520 that would otherwise interact with quantum objects confined by the confinement apparatus 520.

Further, edge facets (e.g., such as those created via the die singulation) expose multiple materials of the ion trap at once, such as waveguide materials, cladding materials, metals, substrates, and/or the like. Different exposed materials may react differently to various processing techniques. For example, different materials may comprise different etch rates. An ion trap that is singulated via stealth dicing would not require substantial additional processing after singulation, such that stealth dicing mitigates risks avoided with changing the edge facet that is exposed after singulation.

In various implementations, the TCO border is transparent in a wavelength range of a laser that is used for stealth dicing. For example, the TCL may be sufficiently transparent (e.g., so as to effectively singulate a portion of a wafer) at near-infrared (near-IR) wavelengths, such as wavelengths between 700 nm and 3,000 nm.

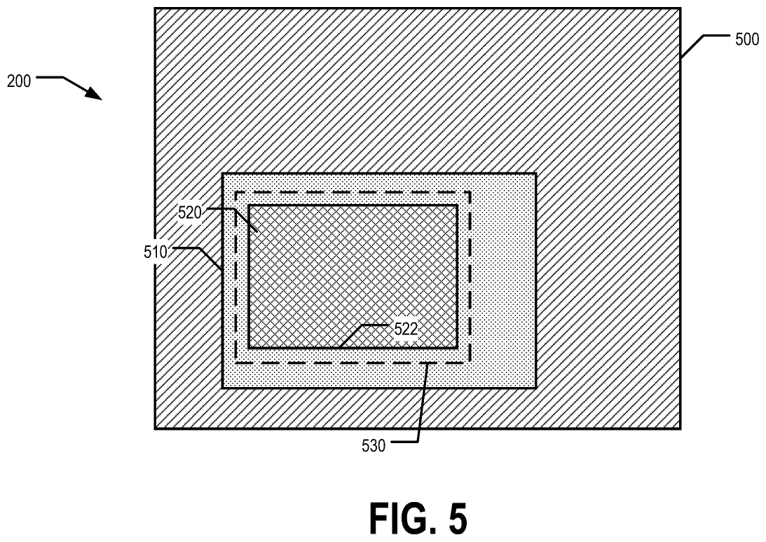

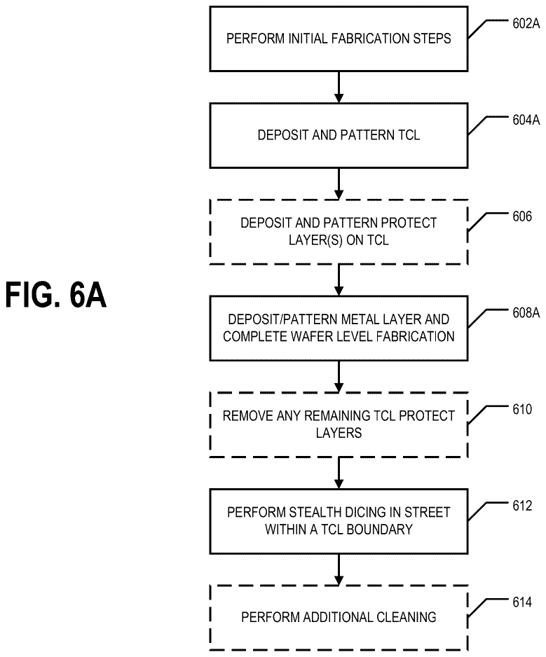

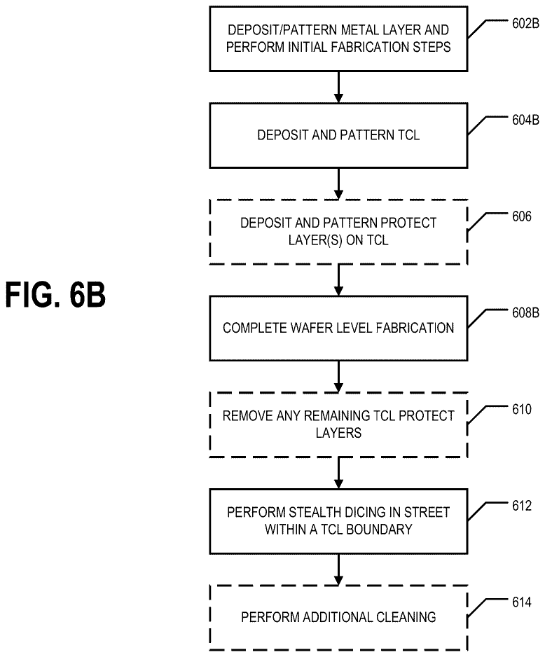

In some implementations, TCO films can require protection strategies to avoid damage from ion trap fabrication steps. However, TCO films may not require protection during stealth dicing. As such, and as described with respect to FIGS. 6 and 7, a TCO protective layer (e.g., a TCO protect) may be formed on the TCO during fabrication and may be subsequently stripped at the wafer level prior to stealth dicing to singulate an ion trap.

### Example Methods of Fabrication

FIGS. 6A and 6B provide, respectively, flowcharts (e.g., methods) 600 and 650 illustrating various processes of fabricating a confinement apparatus having a TCL border in accordance with some embodiments described herein. Devices in accordance with embodiments described herein may be manufactured according to either/both of the methods 600 and 650.

For example, the flowchart 600 of FIG. 6A may be used to fabricate the structures illustrated in FIG. 7 (in which a TCL is deposited on a wafer prior to deposition of a metal layer on the TCL). The flowchart 600 of FIG. 6B may be used to fabricate the confinement apparatus 200 of FIG. 3 (in which a metal layer is deposited on wafer prior to deposition of a TCL on the metal layer). Steps (e.g., elements) of the flowcharts 600 and 650 outlined in dashed boxes may optionally be included and/or excluded during execution of the methods illustrated by the flowcharts.

Beginning with step 602A of FIG. 6A, initial fabrication steps may be performed. One or more such initial fabrication steps may include fabrication of one or more electrical and/or optical/photonic interposer/routing layers, fabrication of one or more vias and/or fabrication of one or more dielectric layers.

At step 604A, one or more transparent conductive layers (TCLs) are deposited and patterned. The TCLs may comprise TCOs, in accordance with some embodiments.

For example, the TCL may be deposited and/or patterned to form a signal manipulation element 342, recessed cap 305, and/or the like. A TCL border 510 is present along at least a portion of the perimeter 522 of the top metal layer of the confinement apparatus 520. The TCL may be deposited and patterned to define at least a first street along which the confinement apparatus is stealth diced for singulation of dies of the confinement apparatus.

In some implementations at 604A of FIG. 6A, the TCL is deposited and then the TCL is patterned. In other implementations, the TCL may be patterned and then the TCL may be deposited. For example, Damascene and/or liftoff-based processing may be performed to patterned the TCL prior to deposition thereof.

At step 606, one or more TCL protective layers may optionally be deposited and patterned to protect the TCL (e.g., to maintain conductivity and/or optical transparency of the TCL) during additional/remaining fabrication steps.

At step 608A, a metal layer (e.g., a top metal layer comprising electrodes) is deposited and/or patterned. Further, any remaining wafer level fabrication steps may be performed. For example, one or more load holes may be etched, gaps and/or undercuts may be etched between adjacent electrodes, patterned conductive layer clean-up processes may be performed, and/or the like.

At step 610, any TCL protect layers that were deposited at optional step 606 and that are still intact may be removed.

At step 612, stealth dicing is performed along a street (e.g., a cut/cleave line, such as the street 530 of FIG. 5) that is disposed within the TCL border along at least a portion of the perimeter (e.g., the perimeter 522 of FIG. 5) of a metal layer of the confinement apparatus and/or other device. For example, stealth dicing may be performed along a street that is disposed within a TCL border along at least a portion of the perimeter of a topmost metal layer comprising at least a first electrode of the confinement apparatus. The TCL border that is disposed along at least a portion of the perimeter of the top metal layer is configured to prevent the accumulation of static charge on the surface of the confinement apparatus that is fabricated according to the flowchart 650.

During the stealth dicing, a laser is focused at a depth within the wafer/layers formed on the wafer. The laser may be focused at a depth within the wafer/layers formed on the wafer that are not photonic layers such that the edges of the photonics layers cleave cleanly/smoothly. For example, the laser may be focused at a depth indicated by line 350 in FIG. 3 such that the laser is not focused within the photonic interposer layer 360 of FIG. 3. The laser may be focused at a depth indicated by line 350 such that the laser is focused within the wafer 302 during stealth dicing.

At step 614, cleaning of the stealth-diced confinement apparatus may optionally be performed. For example, a gentle cleaning of the stealth-diced confinement apparatus may be performed. Edge facets of the confinement apparatus that are exposed after the stealth dicing of step 612 may expose multiple materials of the ion trap at once (e.g., waveguide materials, cladding materials, metals, substrates, and/or the like). Because an ion trap that is singulated via stealth dicing does not require substantial additional processing after singulation, stealth dicing mitigates risks avoided with changing the edge facet that is exposed after singulation. As such, in some implementations, only an additional gentle cleaning of the singulated confinement apparatus may be required.

FIG. 6B illustrates an additional method 650 of fabricating a device in accordance with various embodiments herein. Whereas, in the method 600 of FIG. 6A, the TCL deposition step 604A precedes the metal deposition step 608A, in the method 650 of FIG. 6B, the deposition and/or the patterning of the metal layer occurs with initial fabrication steps 602B, and thus precedes the TCL deposition step 604B.

In particular, as with FIG. 6A, the additional initial fabrication steps 602B may include fabrication of one or more electrical and/or optical/photonic interposer/routing layers, fabrication of one or more vias, and/or fabrication of one or more dielectric layers.

604B of FIG. 6B illustrates that, after the metal deposition and/or patterning is performed with the initial fabrication steps at 602B, the TCL may be deposited and patterned. This stands in contrast to the method of FIG. 6A, in which the TCL is deposited prior to the deposition of the metal layer and in which the TCL is patterned either before the metal layer or therewith. In some implementations at 60BA of FIG. 6A, the TCL is deposited and then the TCL is patterned. In other implementations, the TCL may be patterned and then the TCL may be deposited. For example, Damascene and/or liftoff-based processing may be performed to patterned the TCL prior to deposition thereof.

606B of FIG. 6B illustrates that, after the TCL is deposited and patterned (and, optionally, if step 606 is included), wafer level fabrication is completed. For example, one or more load holes may be etched, gaps and/or undercuts may be etched between adjacent electrodes, patterned conductive layer clean-up processes may be performed, and/or the like.

### Example of Structure Corresponding to FIG. 6A

The various steps of the flowchart 600 of FIG. 6A are further illustrated in FIG. 7.

FIGS. 7A-7D illustrate various steps in the fabrication of a confinement apparatus having a TCO border in accordance with some embodiments described herein. For example, FIGS. 7A-7D illustrate various steps of the flowchart 650 of FIG. 6A that may be used to fabricate a confinement apparatus having a TCL border in accordance with various embodiments described herein.

The result of completing steps 602-606, as well as the metal deposition of step 608A of FIG. 6A is the structure 700 shown in FIG. 7A. In accordance with some embodiments described herein, initial fabrication steps are performed (e.g., one or more electrical and/or optical/photonic interposer/routing layers may be fabricated, vias may be fabricated, one or more dielectric layers may be fabricated, a top metal layer comprising electrodes may be deposited and/or patterned on a wafer, and/or the like), a TCO is deposited and patterned, and a TCO protective layer is deposited and patterned to yield the structure 700 shown in FIG. 7A. In particular, the structure 700 of FIG. 7A comprises a plurality of electrodes 212 (e.g., formed of a top metal layer), the TCO protective layer 702, a TCO 704, an optical layer 706 (corresponding to the dashed line) and a substrate 300, such as the first substrate 300 of FIGS. 3 and 4.

Remaining wafer-level fabrication steps that are required may be performed on the structure 700 of in FIG. 7A, further corresponding to step 608A of the flowchart 650 of FIG. 6. For example, if the electrodes and/or top metal layer has not yet been deposited or patterned, the electrodes and/or top metal layer has not yet been deposited and/or patterned, one or more load holes may be etched, gaps and/or undercuts may be etched between adjacent electrodes, patterned conductive layer clean-up processes may be performed, and/or the like. In the embodiment of FIG. 7A, one load hole 712 is present.

After any remaining wafer-level fabrication steps are completed, the TCO protect 704 is stripped at the wafer level, corresponding to step 610 in the flowchart 650. The result of performing step 610 on the structure 700 of FIG. 7A is the structure 710 shown in FIG. 7B comprising a plurality of electrodes 212 and a TCO 704 disposed on the substrate 300.

FIG. 7C illustrates the stealth dicing 720 (corresponding to the bowtie-shaped structures on the sides of the FIG.) of the structure 710 shown in FIG. 7B, corresponding to step 612 of the flowchart 650. In particular, as shown in FIG. 7C, the system is stealth diced 720 beyond the electrodes 212 (e.g., the top metal layer) but through the TCO 704 and the optical layer 706.

The system is stealth diced 720 along a street defined by the deposition of the TCO. The result is a confinement apparatus having a TCO border disposed in at least a portion of a perimeter defined by a top metal layer (e.g., an electrode) of the confinement apparatus. The TCO border may be configured to reduce and/or prevent the buildup of static electric charge on the surface of the confinement apparatus, as such accumulated charge may, if present, generate electric fields that interact in an undesired manner with quantum objects confined by the confinement apparatus.

As shown in FIG. 7D, the stealth dicing 720 cleaves the structure 730 at the locations where the laser used for stealth dicing 720 drew lines. After having been stealth diced 720 as shown in FIGS. 7C, the resulting structure 730 of FIG. 7D may be subject to gentle clean steps to yield a final confinement apparatus, corresponding to step 614 in the flowchart 650 of FIG. 6. The structure 730 may comprise a plurality of electrodes 212 and a TCO 704 disposed on a substrate 300.

### Exemplary Controller

Various embodiments provide systems comprising confinement apparatus assemblies 200. For example, various atomic systems, quantum systems, and/or the like may use a confinement apparatus assemblies 200 to confine one or more atomic and/or quantum objects. In an example embodiment, the system is a quantum charge-coupled device (QCCD-based) quantum computer 110 or another quantum computer. In various embodiments, the system (e.g., quantum computer 110) includes a controller 30 configured to control various elements of the system. For example, the controller 30 may be configured to control the voltage sources 50, a cryogenic system and/or vacuum system for controlling the temperature and pressure within the cryogenic and/or vacuum chamber 40, manipulation sources 64 (e.g., 64A, 64B, 64C), magnetic field sources 70 (e.g., 70A, 70B), and/or other systems controlling the environmental conditions (e.g., temperature, humidity, pressure, magnetic field gradient, and/or the like) within the cryogenic and/or vacuum chamber 40, configured to manipulate and/or cause a controlled evolution of quantum states of one or more atomic and/or quantum objects confined by the confinement apparatus, and/or read and/or detect a quantum state of one or more atomic and/or quantum objects confined by the confinement apparatus.

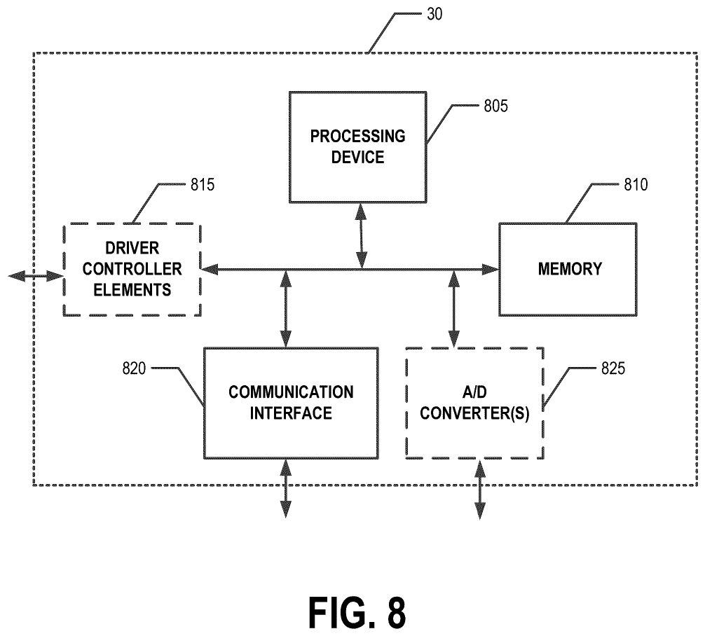

As shown in FIG. 8, in various embodiments, the controller 30 may comprise various controller elements including one or more processing devices 805, memory 810, driver controller elements 815, a communication interface 820, analog-digital converter elements 825, and/or the like. For example, the one or more processing devices 805 may comprise one or more processing elements such as programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. The term circuitry may refer to an entirely hardware embodiment or a combination of hardware and computer program products. In an example embodiment, the one or more processing devices 805 of the controller 30 comprises a clock and/or is in communication with a clock. In various embodiments, this clock defines the clock cycles of the system.

For example, the memory 810 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 810 may store qubit records corresponding the qubits of quantum computer (e.g., in a qubit record data store, qubit record database, qubit record table, and/or the like), a calibration table, an executable queue, computer program code (e.g., in a one or more computer languages, specialized controller language(s), and/or the like), and/or the like. In an example embodiment, execution of at least a portion of the computer program code stored in the memory 810 (e.g., by a processing device 805) causes the controller 30 to perform one or more steps, operations, processes, procedures and/or the like described herein for controlling one or more components of the quantum computer 110 (e.g., voltages sources 50, manipulation sources 64, magnetic field sources 70, and/or the like) to cause a controlled evolution of quantum states of one or more atomic and/or quantum objects, detect and/or read the quantum state of one or more atomic and/or quantum objects, and/or the like.

In various embodiments, the driver controller elements 815 may include one or more drivers and/or controller elements each configured to control one or more drivers. In various embodiments, the driver controller elements 815 may comprise drivers and/or driver controllers. For example, the driver controllers may be configured to cause one or more corresponding drivers to be operated in accordance with executable instructions, commands, and/or the like scheduled and executed by the controller 30 (e.g., by the processing device 805). In various embodiments, the driver controller elements 815 may enable the controller 30 to operate a manipulation source 64. In various embodiments, the drivers may be laser drivers; vacuum component drivers; drivers for controlling the flow of current and/or voltage applied to the segmented electrodes (e.g., the RF, control, and/or other electrodes of the confinement apparatus 220) used for maintaining and/or controlling the confinement potential of the confinement apparatus (and/or other driver for providing driver action sequences and/or control signals to potential generating elements of the confinement apparatus); cryogenic and/or vacuum system component drivers; and/or the like. For example, the drivers may control and/or comprise control and/or RF voltage drivers and/or voltage sources that provide voltages and/or electrical signals to the electrodes (e.g., control electrodes 216 and/or RF electrodes 212). In various embodiments, the controller 30 comprises means for communicating and/or receiving signals from one or more detectors such as optical receiver components (e.g., cameras, MEMs cameras, CCD cameras, photodiodes, photomultiplier tubes, and/or the like) of the optics collection system 80. For example, the controller 30 may comprise one or more analog-digital converter elements 825 configured to receive signals from one or more detectors, optical receiver components, calibration sensors, and/or the like.

In various embodiments, the controller 30 may comprise a communication interface 820 for interfacing and/or communicating with one or more computing entities 10. For example, the controller 30 may comprise a communication interface 820 for receiving executable instructions, command sets, and/or the like from the computing entity 10 and providing output received from the quantum processor 115 (e.g., via the optics collection system 80) and/or the result of a processing the output (received from the quantum processor 115) to the computing entity 10. In various embodiments, the computing entity 10 and the controller 30 may communicate via a direct wired and/or wireless connection and/or one or more wired and/or wireless networks 20.

### Exemplary Computing Entity

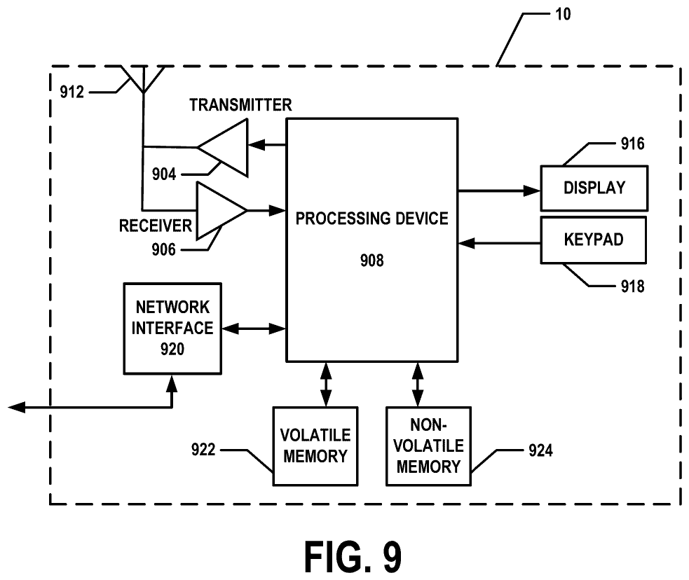

FIG. 9 provides an illustrative schematic representative of an example computing entity 10 that can be used in conjunction with embodiments of the present invention. In various embodiments, a computing entity 10 is configured to allow a user to provide input to the quantum computer 110 (e.g., via a user interface of the computing entity 10) and receive, display, analyze, and/or the like output from the quantum computer 110.

As shown in FIG. 9, a computing entity 10 can include an antenna 912, a transmitter 904 (e.g., radio), a receiver 906 (e.g., radio), and a processing device 908 that provides signals to and receives signals from the transmitter 904 and receiver 906, respectively.

The signals provided to and received from the transmitter 904 and the receiver 906, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system. In various embodiments, the computing entity 10 further comprises one or more network interfaces 920 configured to communicate via one or more wired and/or wireless networks 20.

The computing entity 10 may also comprise a user interface device comprising one or more user input/output interfaces (e.g., a display 816 and/or speaker/speaker driver coupled to a processing device 908 and a touch screen, keyboard, mouse, and/or microphone coupled to a processing device 908). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 918 (hard or soft), a touch display, voice/speech or motion interfaces, scanners, readers, or other input device. In embodiments including a keypad 918, the keypad 918 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 922 and/or non-volatile storage or memory 924, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### CONCLUSION

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A method comprising:
depositing a transparent conductive layer (TCL) on a wafer, the TCL characterized by a TCL border, and
singulating the wafer along at least a first portion of a street that is disposed within the TCL border.

2. The method of claim 1, wherein singulating the wafer comprises stealth dicing the wafer along at least the portion of the street that is disposed within the TCL border.

3. The method of claim 1, further comprising:
depositing a metal layer on a wafer, the metal layer characterized by a perimeter,
wherein the TCL border extends along at least a portion of the perimeter of the metal layer.

4. The method of claim 3, wherein the metal layer is deposited on the wafer before the TCL is deposited on the wafer.

5. The method of claim 4, further comprising:
patterning the metal layer before the TCL is deposited on the wafer, and
patterning the TCL after the TCL is deposited on the wafer.

6. The method of claim 3, wherein the TCL is deposited on the wafer before the metal layer is deposited on the wafer.

7. The method of claim 6, further comprising:
patterning the TCL before the metal layer is deposited on the wafer, and patterning the metal layer after the metal layer is deposited on the wafer.

8. The method of claim 6, further comprising:
patterning the TCL and the metal layer after the metal layer is deposited on the wafer.

9. The method of claim 1, wherein the TCL comprises a transparent conductive oxide (TCO).

10. The method of claim 1, wherein the TCL is transparent in a wavelength range used for stealth dicing the wafer along the street.

11. A device comprising:
a portion of a wafer; and
one or more layers formed on the portion of the wafer, wherein a transparent conductive layer (TCL) border is present along at least a portion of a perimeter of a first layer of the one or more layers.

12. The device of claim 11, wherein the first layer of the one or more layers comprises a metal layer.

13. The device of claim 12, wherein the metal layer and the TCL border are disposed on an exposed surface of the device.

14. The device of claim 12, wherein the device is a confinement apparatus and the metal layer comprises a plurality of electrodes.

15. The device of claim 12, wherein the device is an ancillary chip, including at least one of a bridge chip, a cloud chip, and an external chip.

16. The device of claim 11, wherein the TCL border comprises a TCL that is transparent in a wavelength range of a laser used to perform stealth dicing of the wafer to singulate the portion of the wafer therefrom.

17. The device of claim 12, wherein the one or more layers includes a photonics routing layer.

18. The device of claim 17, wherein the photonics routing layer is configured to cross a street disposed within the TCL border.

19. The device of claim 12, wherein the portion of the wafer is formed from singulating the wafer along a street, the street disposed within the TCL border and along at least a portion of the perimeter of the first layer of the one or more layers.

20. The device of claim 19, wherein singulating the wafer along the street comprises stealth dicing the wafer along the street.
